(19) United States
(12) Patent Application Publication
(10) Pub. No.: US 2026/0076035 A1
(43) Pub. Date: Mar. 12, 2026

(54) ARRAY SUBSTRATE AND MANUFACTURING METHOD THEREFOR, AND DISPLAY PANEL AND DISPLAY APPARATUS

(71) Applicants: Yunnan Invensight Optoelectronics Technology Co., Ltd., Yunnan (CN); BOE Technology Group Co., Ltd., Beijing (CN)

(72) Inventors: Yaoxi MA, Beijing (CN); Longfei FAN, Beijing (CN); Pengcheng LU, Beijing (CN); Shanghong JIANG, Beijing (CN); Shengji YANG, Beijing (CN); Xiaochuan CHEN, Beijing (CN); Dachao LI, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 19/105,832

(22) PCT Filed: Oct. 13, 2023
(86) PCT No.: PCT/CN2023/124528

§ 371 Date: Feb. 24, 2025

(30) Foreign Application Priority Data
Oct. 25, 2022 (CN) 202211313180.X

(51) Int. Cl. H10K 59/121; H10K 59/12; H10K 59/131

(52) U.S. Cl. CPC H10K 59/1216; H10K 59/1201; H10K 59/1213; H10K 59/131

(57) ABSTRACT

The present application relates to an array substrate, which comprises: a driving backplane, in which a plurality of pixel circuits are formed, wherein capacitors of the plurality of pixel circuits comprise first capacitors and a second capacitor, a first electrode plate of each first capacitor has a first side edge, a first electrode plate of the second capacitor has a second side edge, the first side edge is opposite the second side edge, and a first included angle is formed between a straight line where the first side edge is located and a straight line where the second side edge is located, which is an acute angle.

### CROSS-REFERENCE TO RELATED APPLICATIONS

The present application is a national phase application of International Application No. PCT/CN2023/124528, filed on Oct. 13, 2023, which claims priority to Chinese Patent Application No. 202211313180.X, filed on Oct. 25, 2022, entitled “ARRAY SUBSTRATE AND MANUFACTURING METHOD THEREFOR, AND DISPLAY PANEL AND DISPLAY APPARATUS”, and the entire contents thereof are incorporated herein by reference.

### TECHNICAL FIELD

The present disclosure relates to the field of display technology, and in particular, to an array substrate and a manufacturing method therefor, a display panel, and a display device.

### BACKGROUND

The display effect of the display device increases as the PPI of the display device increases. The increasing of the PPI is not only limited by the arrangement density of the light-emitting devices formed in the light-emitting layer, but also by the arrangement density of the pixel circuit formed in the driving backplane.

It should be noted that, information disclosed in the above background portion is provided only for better understanding of the background of the present disclosure, and thus it may contain information that does not form the prior art known by those ordinary skilled in the art.

### SUMMARY

The objective of the present disclosure is to provide an array substrate and a manufacturing method thereof, a display panel, and a display device.

According to one aspect of the present disclosure, there is provided an array substrate, including:
a driving backplane, formed with a plurality of pixel circuits, wherein the pixel circuits includes capacitors having a first electrode plate and a second electrode plate, and projections of the first electrode plate and the second electrode plate in a thickness direction of the driving backplane have an overlapping area, wherein the capacitors includes a first capacitor and a second capacitor adjacent to each other, wherein the first electrode plate of the first capacitor has a first side, and the first electrode plate of the second capacitor has a second side, wherein the first side is opposite to the second side, and wherein a straight line where the first side is located and a straight line where the second side is located form a first angle, and the first angle is an acute angle.

According to any array substrate described in the present disclosure, the driving backplane includes a top metal layer, the top metal layer includes a first conductive sheet and a second conductive sheet arranged at intervals, one pixel circuit includes a driving transistor, and a projection of a control electrode of the driving transistor in the thickness direction of the driving backplane and a projection of the first conductive sheet in the thickness direction of the driving backplane have an overlapping area;
one of the first electrode plate and the second electrode plate is connected to the first conductive sheet, the first conductive sheet is connected to the control electrode of the driving transistor through a first via hole, the first electrode of the driving transistor is connected to the second conductive sheet, the second electrode of the driving transistor is used to load a voltage signal, and the second conductive sheet is used to connect to the light-emitting device through a second via hole; and
a cross section of the first via hole is a polygon, an edge of the first via hole connected to the first capacitor faces the first side or an extension line of the first side, and a side wall of the first via hole connected to the first capacitor faces the second side.

According to any array substrate described in the present disclosure, the driving backplane further includes a third conductive sheet on a same layer as the first electrode plate, and the third conductive sheet is respectively connected to the first conductive sheet and the control electrode of the driving transistor; and
the third conductive sheet is polygonal in shape, a corner of the third conductive sheet connected to the first capacitor faces the first side or the extension line of the first side, and a side of the third conductive sheet connected to the first capacitor faces the second side.

According to any array substrate described in the present disclosure, the pixel circuit includes a write transistor, a first electrode of the write transistor is connected to the first conductive sheet, a second electrode of the write transistor is used to load a data signal, and a control electrode of the write transistor is used to load a scan signal.

According to any array substrate described in the present disclosure, the pixel circuit includes a switching transistor, a control electrode of the switching transistor is used to load an enable signal, a first electrode of the switching transistor is connected to a first electrode of the driving transistor, and a second electrode of the switching transistor is connected to the second conductive sheet.

According to any array substrate described in the present disclosure, the driving backplane includes a base substrate and a wiring layer, the driving transistor is integrated on the base substrate, and the wiring layer includes the first electrode plate, the second electrode plate and the top metal layer.

According to any array substrate described in the present disclosure, the plurality of capacitors include a plurality of groups of capacitors distributed in an array, and one group of capacitors includes one second capacitor and six first capacitors located at a periphery of the second capacitor and distributed along a circumferential direction; and
two adjacent groups of capacitors in a row direction share one first capacitor, and two adjacent groups of capacitors in a column direction share two first capacitors.

According to any array substrate described in the present disclosure, in a group of the capacitors, the six first capacitors are symmetrically distributed with respect to a center line of the first electrode plate of the second capacitor in a column direction; and
the six first capacitors includes a first sub-capacitor, a second sub-capacitor and a third sub-capacitor located on a same side of the center line of the second capacitor in the column direction, a center line of the first sub-capacitor in the row direction coincides with a center line of the second capacitor in the row direction, the second sub-capacitor and the third sub-capacitor are symmetrically distributed with respect to the center line of the first electrode plate of the second capacitor in the row direction, and in the row direction, a center point of the second sub-capacitor is located between the first sub-capacitor and the second capacitor.

According to any array substrate described in the present disclosure, the first electrode plate of the capacitor is rectangular, each of four sides of the first electrode plate of the second capacitor have a first via and a second via connected to a same capacitor among the first capacitor and the second capacitor, and the first via and the second via connected to the same capacitor are symmetrically distributed with respect to a perpendicular bisector of a corresponding side of the first electrode plate of the second capacitor.

According to any array substrate described in the present disclosure, the driving backplane includes a first metal layer and a second metal layer, the first metal layer includes the first electrode plate of the capacitor, and the second metal layer includes the second electrode plate of the capacitor; and
the projection of the second electrode plate in the thickness direction of the driving backplane is located within the projection of the first electrode plate in the thickness direction of the driving backplane.

According to any array substrate described in the present disclosure, a first angle formed by the straight lines where the first side and the second side are located is greater than or equal to 5 degrees and less than or equal to 80 degrees.

According to any array substrate described in the present disclosure, a first angle formed by the straight lines where the first side and the second side are located is 45 degrees.

According to any array substrate described in the present disclosure, a distance between the first electrode plate of the first capacitor and the first electrode plate of the second capacitor is less than 2a+b, parameter a refers to a minimum safe gap between the first electrode plate and the first via hole, and parameter b is a side length of the cross section of the first via hole.

According to another aspect of the present disclosure, there is provided a method for manufacturing an array substrate, wherein the method includes:
forming a driving backplane, wherein the driving backplane is formed with a plurality of pixel circuits, wherein the pixel circuits includes capacitors having a first electrode plate and a second electrode plate, and projections of the first electrode plate and the second electrode plate in a thickness direction of the driving backplane have an overlapping area, wherein the capacitors includes a first capacitor and a second capacitor adjacent to each other, wherein the first electrode plate of the first capacitor has a first side, and the first electrode plate of the second capacitor has a second side, wherein the first side is opposite to the second side, and wherein a straight line where the first side is located and a straight line where the second side is located form a first angle, and the first angle is an acute angle.

According to yet another aspect of the present disclosure, there is provided a display panel, including:
the array substrate according to the above one aspect; and
a light-emitting layer, disposed on a side of the driving backplane, wherein the light-emitting layer is formed with a plurality of light-emitting devices, and one of the pixel circuits is connected to at least one of the light-emitting devices.

According to still another aspect of the present disclosure, there is provided a display device, includes the display panel according to above yet another aspect.

It is to be understood that both the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for those skilled in the art, other accompanying drawings can be obtained based on these accompanying drawings without creative effort.

FIG. 1 is a schematic diagram of a partial cross-sectional structure of a display panel provided in an embodiment of the present disclosure.

FIG. 2 is a schematic diagram of the structure of a pixel circuit provided in an embodiment of the present disclosure.

FIG. 3 is a schematic diagram of a partial cross-sectional structure of another display panel provided in an embodiment of the present disclosure.

FIG. 4 is a schematic diagram of the arrangement of storage capacitors in a pixel region provided by the related art.

FIG. 5 is a schematic diagram of the arrangement of storage capacitors in a pixel region provided in an embodiment of the present disclosure.

FIG. 6 is a schematic diagram of the arrangement of storage capacitors within multiple pixels provided by the related art.

FIG. 7 is a schematic diagram of the arrangement of storage capacitors within multiple pixels provided in an embodiment of the present disclosure.

FIG. 8 is a schematic diagram of a partial arrangement of storage capacitors in a pixel region provided in an embodiment of the present disclosure.

FIG. 9 is a schematic diagram of another arrangement of storage capacitors in a pixel region provided in an embodiment of the present disclosure.

FIG. 10 is a schematic structural diagram of a method for connecting storage capacitors in a pixel region provided in an embodiment of the present disclosure.

FIG. 11 is a schematic structural diagram of another method for connecting storage capacitors in a pixel region provided in an embodiment of the present disclosure.

### DETAILED DESCRIPTION

Example embodiments will now be described more fully with reference to the accompanying drawings. However, the example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in this specification to describe the relative relationship of one component of the illustration to another component, these terms are used in this specification only for convenience, such as according to the orientation of the examples described in the drawings. It is understood that if the device of the illustration is turned upside down, the component described as “upper” will become the component “lower”. When a structure is “on” other structures, it may mean that the structure is formed integrally on the other structure, or that the structure is “directly” disposed on the other structure, or that the structure is “indirectly” disposed on the other structure through another structure.

The terms “a”, “an”, “the”, “said” and “at least one” are used to indicate the presence of one or more elements/components/etc. ; the terms “including” and “having” are used to express an open-ended inclusive meaning and mean that additional elements/components/etc. may exist in addition to the listed elements/components/etc. ; the terms “first”, “second” and “third” etc. are used merely as labels and are not intended to limit the quantity of their objects.

In the present disclosure, a transistor refers to an element including at least three terminals: a gate, a drain, and a source. The transistor has a channel region between the drain (drain terminal, drain region, or drain electrode) and the source (source terminal, source region, or source electrode), and current can flow through the drain, the channel region, and the source. The channel region refers to the region where the current mainly flows. In the case of using transistors of opposite types or the case where the current direction changes during circuit operation, the functions of the “source” and the “drain” are sometimes interchanged. Therefore, in the present disclosure, the “source” and the “drain” can be interchanged. Structurally, a transistor can have a first electrode, a second electrode, and a control electrode, wherein the gate of the transistor can be used as the control electrode of the transistor; one of the source and the drain of the transistor can be used as the first electrode of the transistor, and the other can be used as the second electrode of the transistor.

In the present disclosure, the “on” state of a transistor refers to a state in which the source and drain of the transistor are electrically connected. The “off” state of a transistor refers to a state in which the source and drain of the transistor are electrically disconnected; it is understood that when the transistor is off, leakage current may still exist.

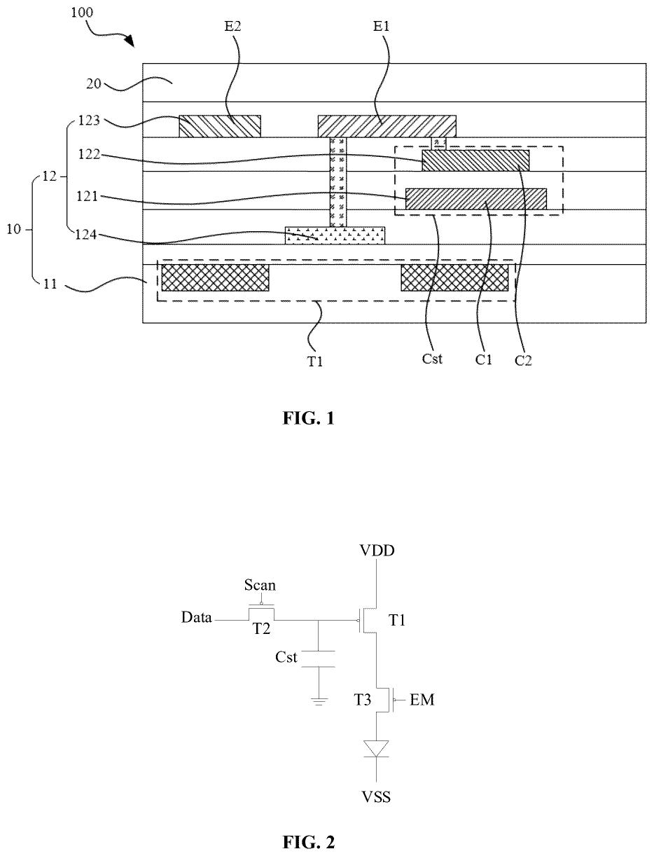

The embodiment of the present disclosure provides a display panel 100. As shown in FIG. 1, the display panel 100 includes an array substrate 10 and a light-emitting layer 20. The array substrate 10 is formed with a plurality of pixel circuits. The light-emitting layer 20 is located on one side of the array substrate 10 and is formed with a plurality of light-emitting devices. One pixel circuit is connected to at least one corresponding light-emitting device (for example, one pixel circuit is connected to one corresponding light-emitting device). In this way, the corresponding light-emitting device can be driven by the pixel circuit to emit light, thereby realizing the display of image.

Multiple pixel circuits can be distributed in an array, and the pixel circuit can be 1T1C, 2T1C, 7T1C and other circuits, as long as it can drive at least one corresponding light-emitting device to emit light, and the embodiments of the present disclosure do not make special restrictions on this. nTmC means that a pixel circuit includes n transistors (represented by the letter “T”) and m capacitors Cst (represented by the letter “C”).

The capacitor Cst included in the pixel circuit may be a storage capacitor Cst, a parasitic capacitor Cst, etc. Of course, each pixel circuit may also include both a storage capacitor Cst and a parasitic capacitor Cst. For the same type of capacitors Cst included in multiple pixel circuits, the projection areas of the capacitors Cst in the thickness direction of the display panel 100 are equal (the equality here refers to the equality in theoretical design, and does not limit the error caused by the manufacturing process), so as to ensure that the electrical parameters of each pixel circuit are the same, and then ensure that the light-emitting device corresponding to each pixel circuit has the same light-emitting effect when emitting light.

By way of example, the pixel circuit includes a driving transistor T1 and a capacitor Cst, wherein a first electrode of the driving transistor T1 is connected to at least one corresponding light-emitting device, a second electrode of the driving transistor T1 is used to load a voltage signal, a control electrode of the driving transistor T1 is used to write a data signal, and the control electrode of the driving transistor T1 is grounded through the capacitor Cst; or the control electrode of the driving transistor T1 is connected to the second electrode of the driving transistor T1 through the capacitor Cst.

Furthermore, the pixel circuit further includes a write transistor T2, a first electrode of the write transistor T2 is connected to the control electrode of the drive transistor T1, a second electrode of the write transistor T2 is used to load a data signal, and a control electrode of the write transistor T2 is used to load a scan signal.

For example, taking the pixel circuit of 3T1C circuit as an example, as shown in FIG. 2, the pixel circuit includes a driving transistor T1, a writing transistor T2, a switching transistor T3 and a capacitor Cst, the first electrode of the driving transistor T1 is connected to the first electrode of the switching transistor T3, the second electrode of the driving transistor T1 is used to load the voltage signal VDD, the control electrode of the driving transistor T1 is connected to the second electrode of the writing transistor T2, and is grounded through the capacitor Cst, the first electrode of the writing transistor T2 is used to load the data signal Data, the control electrode of the writing transistor T2 is used to load the scanning signal Scan, the second electrode of the switching transistor T3 is connected to at least one corresponding light-emitting device, and the control electrode of the switching transistor T3 is used to load the enable signal EM.

The array substrate 10 has a plurality of pixel areas DCAA, and each pixel area DCAA has a plurality of pixel circuits, for example, three pixel circuits, four pixel circuits, etc. For example, in the case of three pixel circuits, the three pixel circuits are respectively used to drive a red light-emitting device, a green light-emitting device, and a blue light-emitting device; for example, in the case of four pixel circuits, the four pixel circuits are respectively used to drive a red light-emitting device, a green light-emitting device, a blue light-emitting device, and a white light-emitting device.

In some embodiments, the display panel 100 may further include a thin film encapsulation layer. The thin film encapsulation layer is disposed on a side of the light emitting layer 20 away from the array substrate 10, and the thin film encapsulation layer may include an inorganic encapsulation layer and an organic encapsulation layer alternately stacked.

The inorganic encapsulation layer can effectively block external moisture and oxygen, preventing water and oxygen from invading the organic light-emitting functional layer and causing material degradation; the organic encapsulation layer is located between two adjacent inorganic encapsulation layers to achieve planarization and reduce the stress between the inorganic encapsulation layers.

The display panel 100 has a display area and a peripheral area located outside the display area, the edge of the inorganic encapsulation layer can be located in the peripheral area, and the edge of the organic encapsulation layer can be located between the edge of the display area and the edge of the inorganic encapsulation layer. Exemplarily, the thin film encapsulation layer includes a first inorganic encapsulation layer, an organic encapsulation layer, and a second inorganic encapsulation layer sequentially stacked on the side of the light emitting layer 20 away from the array substrate 10.

In some embodiments, the display panel 100 may further include a touch function layer, which is disposed on a side of the thin film encapsulation layer away from the array substrate 10, and is used to implement a touch operation of the display panel 100.

In the embodiment of the present disclosure, as shown in FIG. 1, the array substrate 10 includes a driving backplane. The driving backplane includes a base substrate 11 and a wiring layer 12 located on a side of the base substrate 11.

The driving backplane is formed with the aforementioned plurality of pixel circuits, and the light emitting layer 20 is located on a side of the wiring layer 12 away from the base substrate 11.

The base substrate 11 can be any transparent substrate, such as a glass substrate, a quartz substrate, a plastic substrate or other transparent rigid or flexible substrate, which can be a single-layer or multi-layer structure. Taking the multi-layer structure as an example, the base substrate 11 includes a first PI (polyimide) layer, a first protective layer, a second PI (polyimide) layer, and a second protective layer stacked from bottom to top. The two protective layers are used to protect the PI layer to prevent the subsequent process from damaging the PI layer. The second protective layer is also covered with a buffer layer, which can block water oxygen and block alkaline ions. Of course, the base substrate 11 can also be a silicon substrate, such as single crystal silicon or high-purity silicon. At this time, as shown in FIG. 1, the silicon substrate is integrated with the transistors (such as the driving transistor T1, etc.) included in the above-mentioned pixel circuit. For example, the control electrode (i.e., the semiconductor layer), the first electrode and the second electrode of the transistor are formed in the silicon substrate by a doping process.

The wiring layer 12 includes multiple metal layers and insulating film layers arranged on both sides of any metal layer. In combination with the above, when the base substrate 11 is a transparent substrate, the wiring layer 12 is formed with multiple pixel circuits, that is, is formed with the respective transistors and capacitors Cst included in each pixel circuit, and the connection lines between each transistor, capacitor Cst and signal loading line; when the base substrate 11 is a silicon substrate, since each pixel circuit includes transistors integrated on the base substrate 11, the wiring layer 12 is only formed with the capacitor Cst included in each pixel circuit, and the connection lines between each transistor, capacitor Cst and signal loading line.

The capacitor Cst included in the pixel circuit includes a first electrode plate C1 and a second electrode plate C2. In this case, as shown in FIG. 1, the wiring layer 12 includes a first metal layer 121 and a second metal layer 122. The first metal layer 121 includes the first electrode plate C1 of the capacitor Cst, and the second metal layer 122 includes the second electrode plate C2 of the capacitor Cst, and the first electrode plate C1 and the second electrode plate C2 have an overlapping area in the thickness direction of the driving backplane.

The first electrode plate C1 can be the upper electrode plate of the capacitor Cst (that is, the electrode plate close to the light-emitting layer 20), and the second electrode plate C2 can be the lower electrode plate of the capacitor Cst (that is, the electrode plate away from the light-emitting layer 20). In this case, the second metal layer 122 is located between the first metal layer 121 and the base substrate 11; it can also be as shown in FIG. 1, the first electrode plate C1 can be the lower electrode plate of the capacitor Cst, and the second electrode plate C2 can be the upper electrode plate of the capacitor Cst. In this case, the first metal layer 121 is located between the second metal layer 122 and the base substrate 11.

Optionally, the first electrode plate C1 and the second electrode plate C2 may both be polygonal (of course, due to limitations of the manufacturing process when actually manufacturing the first electrode plate C1 and the second electrode plate C2, the first electrode plate C1 and the second electrode plate C2 are not strictly polygonal, for example, the corners of the electrode plates have arc chamfers). For example, the first electrode plate C1 and the second electrode plate C2 may both be rectangular or hexagonal, etc., and the embodiments of the present disclosure are not limited to this.

In combination with the above-mentioned case that the control electrode of the driving transistor T1 is grounded through the capacitor Cst, in this case, one of the first electrode plate C1 and the second electrode plate C2 is connected to the control electrode of the driving transistor T1, and the other is grounded; or in combination with the above-mentioned case that the capacitor Cst connects the control electrode and the second electrode of the driving transistor T1, in this case, one of the first electrode plate C1 and the second electrode plate C2 is connected to the control electrode of the driving transistor T1, and the other is connected to the second electrode of the driving transistor T1.

For the case where one of the first electrode plate C1 and the second electrode plate C2 is connected to the control electrode of the driving transistor T1, optionally, the wiring layer 12 also includes a top metal layer 123, the first metal layer 121 and the second metal layer 122 are both located between the top metal layer 123 and the base substrate 11, and one of the first electrode plate C1 and the second electrode plate C2 is connected to the top metal layer 123, and then the top metal layer 123 is connected to the control electrode of the driving transistor T1 through the first via V1.

For example, as shown in FIG. 1, the first electrode plate C1 of the capacitor Cst is the lower electrode plate, the second electrode plate C2 of the capacitor Cst is the upper electrode plate, and the second electrode plate C2 is connected to the top metal layer 123, and the top metal layer 123 is connected to the control electrode of the driving transistor T1 through the first via V1.

The connection through the first via hole V1 refers to the connection between the top metal layer 123 and the control electrode of the driving transistor T1 directly through the first via hole V1, or the connection is achieved through the cooperation of the first via hole V1 and other conductive parts, which is not limited in the embodiments of the present disclosure. For example, the top metal layer 123 is connected to the control electrode of the driving transistor T1 through the first via hole V1, the third conductive sheet E3 and other vias.

Optionally, the top metal layer 123 includes a first conductive sheet E1, and there is an overlapping area between the control electrode of the driving transistor T1 and the projection of the first conductive sheet E1 in the thickness direction of the driving backplane. In this case, one of the first electrode C1 and the second electrode C2 is connected to the first conductive sheet E1, and the first conductive sheet E1 is connected to the control electrode of the driving transistor T1 through the first via V1. The first electrode of the driving transistor T1 is used to connect to a light-emitting device, and the second electrode of the driving transistor T1 is used to load a voltage signal.

Alternatively, the top metal layer 123 includes a first conductive sheet E1 and a second conductive sheet E2 that are spaced apart, and there is an overlapping area between the control electrode of the driving transistor T1 and the projection of the first conductive sheet E1 in the thickness direction of the driving backplane. In this case, one of the first electrode plate C1 and the second electrode plate C2 is connected to the first conductive sheet E1, and the first conductive sheet E1 is connected to the control electrode of the driving transistor T1 through the first via hole V1, the first electrode of the driving transistor T1 is connected to the second conductive sheet E2, and the second conductive sheet E2 is connected to a light-emitting device through the second via hole V2, and the second electrode of the driving transistor T1 is used to load a voltage signal.

For example, as shown in FIG. 1, the top metal layer 123 includes a first conductive sheet E1 and a second conductive sheet E2 which are spaced apart, the second electrode C2 is the upper electrode of the capacitor Cst, the second electrode C2 is connected to the first conductive sheet E1, and the first conductive sheet E1 is connected to the control electrode of the driving transistor T1 through the first via V1, the first electrode of the driving transistor T1 is connected to the second conductive sheet E2, and the second conductive sheet E2 is connected to the light-emitting device through the second via V2.

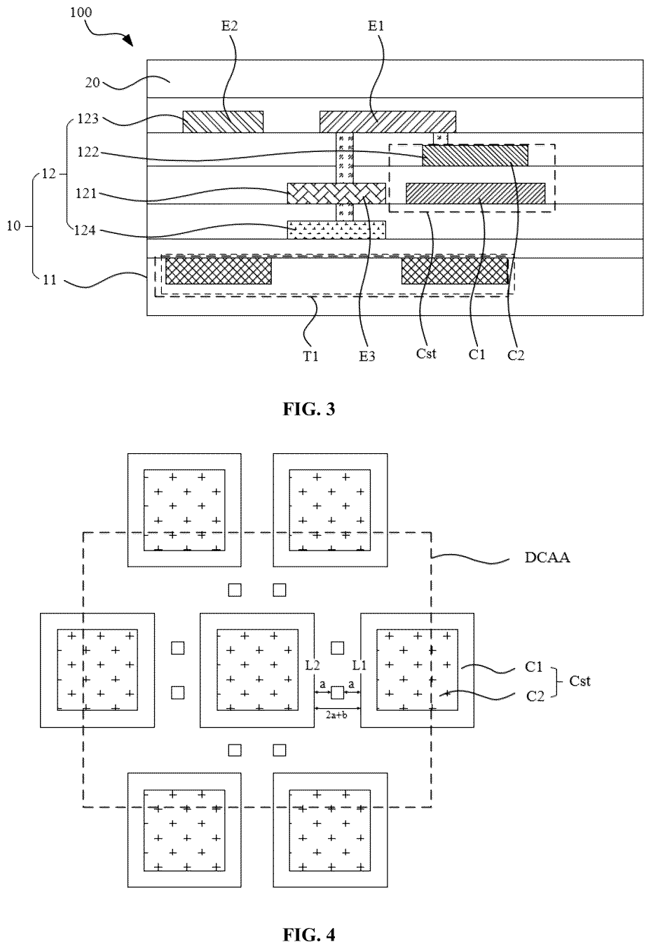

It should be noted that the third conductive sheet E3 mentioned above can be located in the first metal layer 121, or in the second metal layer 122, and of course can also be located in other metal layers. In the case where the top metal layer 123 includes the first conductive sheet E1, as shown in FIG. 3, the third conductive sheet E3 is respectively connected to the first conductive sheet E1 and the control electrode of the driving transistor T1 through vias. In this way, by providing the third conductive sheet E3, not only the transiting between the first conductive sheet E1 and the driving transistor T1 can be realized, but also the connection between the first conductive sheet E1 and other structures can be realized. For example, the connection between the first conductive sheet E1 and other transistors (write transistor T2) included in the pixel circuit is realized through the third conductive sheet E3.

In the case where the top metal layer 123 is formed with a first conductive sheet E1 and a second conductive sheet E2, and in combination with the above-mentioned pixel circuit including a writing transistor T2, the first electrode of the writing transistor T2 is connected to the first conductive sheet E1, and the second electrode of the writing transistor T2 is used to load a data signal; in combination with the above-mentioned pixel circuit including a switching transistor T3, the first electrode of the switching transistor T3 is connected to the first electrode of the driving transistor T1, and the second electrode of the switching transistor T3 is connected to the second conductive sheet E2.

In addition, in the embodiment of the present disclosure, combined with the above, when the base substrate 11 is a silicon substrate, the transistors included in the pixel circuit are integrated in the silicon substrate. In this case, the silicon substrate only formed with the source and drain of each transistor, and the channel region located between the source and the drain. In this case, as shown in FIG. 1 or FIG. 3, the wiring layer 12 further includes a third metal layer 124, and the third metal layer 124 is located on a side close to the base substrate 11, and the third metal layer 124 is formed with the control electrode of each transistor on the base substrate 11 to facilitate the connection of each transistor in the pixel circuit.

In the embodiment of the present disclosure, for the first electrode plate C1 and the second electrode plate C2 included in the capacitor Cst, it can be that: the projection of the second electrode plate C2 in the thickness direction of the driving backplane is located within the projection of the first electrode plate C1 in the thickness direction of the driving backplane, or the projection of the first electrode plate C1 in the thickness direction of the driving backplane and the projection of the second electrode plate C2 in the thickness direction of the driving backplane are extended beyond each other.

For the case where the projection of the second electrode plate C2 in the thickness direction of the driving backplane is located within the projection of the first electrode plate C1 in the thickness direction of the driving backplane, the arrangement of the multiple capacitors Cst can be determined according to the arrangement of the first electrode plate C1; and for the case where the projection of the first electrode plate C1 in the thickness direction of the driving backplane and the projection of the second electrode plate C2 in the thickness direction of the driving backplane are extended beyond each other, the arrangement of the multiple capacitors Cst can be determined according to the arrangement of the second electrode plate C2, or the arrangement of the multiple capacitors Cst can be determined according to the arrangement of the second electrode plate C2, or the arrangement of the multiple capacitors Cst can be determined according to the arrangement of the first electrode plate C1 and the second electrode plate C2.

In the related art, the electrode plates of the capacitors Cst included in respective pixel circuits are distributed in an array (that is, the first electrode plates C1 and the second electrode plates C2 of the multiple capacitors Cst each have a side parallel to each other) so as to increase the distribution density of the capacitor Cst in the array substrate 10 while ensuring a safe gap between two adjacent capacitors Cst, so as to improve the PPI of the display panel 100.

Taking the adjacent first capacitor Cst1 and second capacitor Cst2 as an example, assuming that the projection of the second electrode plate C2 in the thickness direction of the driving backplane is located within the projection of the first electrode plate C1 in the thickness direction of the driving backplane, as shown in FIG. 4, the first electrode plate C1 of the first capacitor Cst1 has a first side L1, and the first electrode plate C1 of the second capacitor Cst2 has a second side L2, and the first side L1 is opposite and parallel to the second side L2. In this case, in combination with FIG. 4, it can be seen that the distance between the first electrode plate C1 of the first capacitor Cst1 and the first electrode plate C1 of the second capacitor Cst2 is 2a+b. In the embodiment, the parameter a refers to the minimum safe gap between the capacitor Cst and the via, and the parameter b is the side length of the cross section of the rectangular via between the first capacitor Cst1 and the second capacitor Cst2.

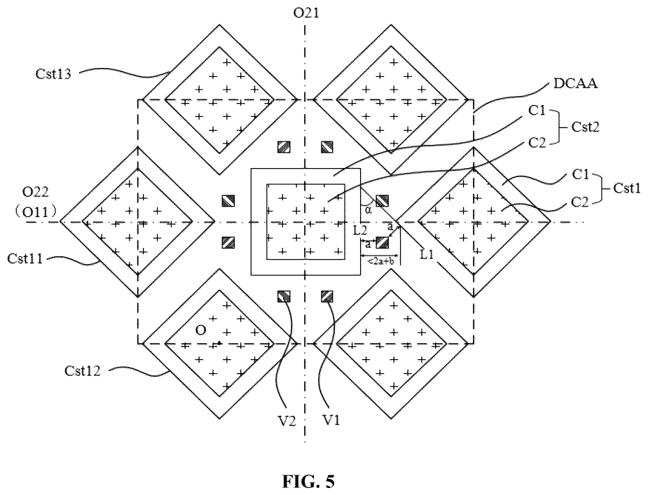

In the embodiment of the present disclosure, the capacitor Cst included in the plurality of pixel circuits includes adjacent first capacitor Cst1 and second capacitor Cst2. As shown in FIG. 5, for the adjacent first capacitor Cst1 and second capacitor Cst2, the first electrode plate C1 of the first capacitor Cst1 has a first side L1, the first electrode plate C1 of the second capacitor Cst2 has a second side L2, the first side L1 is opposite to the second side L2, and the straight lines where the first side L1 and the second side L2 are located form a first angle a, which is an acute angle. In this case, in conjunction with FIG. 5, it can be seen that the distance between the first electrode plate C1 of the first capacitor Cst1 and the first electrode plate C1 of the second capacitor Cst2 is less than 2a+b. In this way, compared with the related art, the embodiment of the present disclosure can reduce the distance between the first electrode plate C1 of the first capacitor Cst1 and the first electrode plate C1 of the second capacitor Cst2, thereby increasing the arrangement density of the capacitor Cst in the array substrate 10 while increasing the arrangement density of the first electrode plate C1, thereby facilitating further improvement of the PPI of the display panel 100.

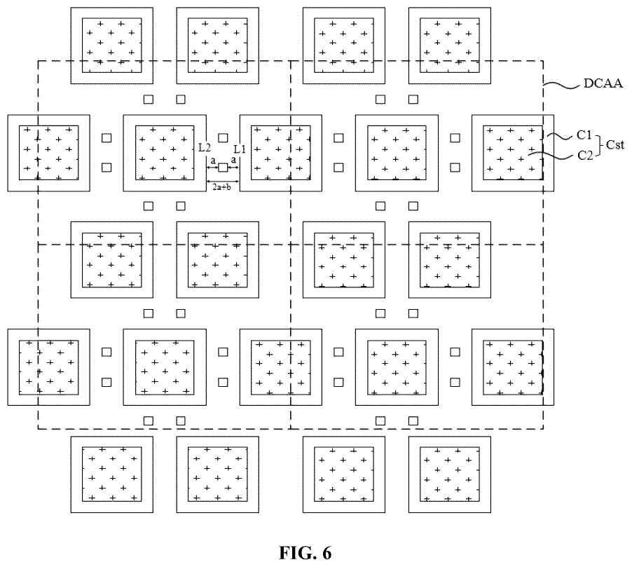

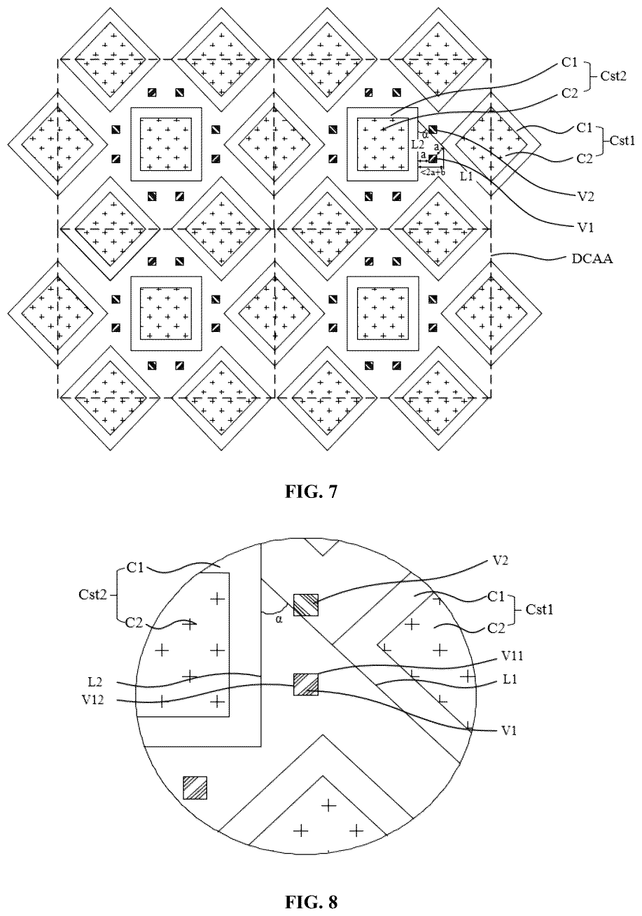

In addition, taking the size of a pixel area DCAA of the present disclosure as an example, assuming that the shape of the first electrode plate C1 included in the capacitor Cst is rectangular, in the related art, the arrangement of the capacitors Cst in four pixel areas DCAA is shown in FIG. 6, and the arrangement of the capacitors Cst in four pixel areas DCAA in the present disclosure is shown in FIG. 7. Thus, in combination with FIG. 6 and FIG. 7, it can be seen that the arrangement of the first electrode plate C1 included in the capacitor Cst in the present disclosure can further improve the arrangement density of the capacitor Cst in the array substrate 10, thereby facilitating further improving the PPI of the display panel 100.

Optionally, the first angle a formed by the straight lines where the first side L1 and the second side L2 are located is greater than or equal to 5 degrees and less than or equal to 80 degrees. For example, the first angle a formed by the straight lines where the first side L1 and the second side L2 are located is 15 degrees, 30 degrees, 45 degrees, 60 degrees, 75 degrees, etc. For example, as shown in FIG. 7, the first angle a formed by the straight lines where the first side L1 and the second side L2 are located is 45 degrees, so as to optimize the distance between the first capacitor Cst1 and the second capacitor Cst2.

In the embodiment of the present disclosure, in addition to determining the arrangement of the first electrode plate C1 included in two adjacent capacitors Cst, for the case where the projection of the second electrode plate C2 in the thickness direction of the driving backplane is located within the projection of the first electrode plate C1 in the thickness direction of the driving backplane, the minimum safety gap between the second electrodes C2 of the two adjacent capacitors Cst is certainly satisfied, and the arrangement of the second electrodes C2 of the two adjacent capacitors Cst will not affect the overall arrangement of the capacitors Cst, so the arrangement of the second electrode plate C2 can be ignored.

As for the case where the projection of the first electrode plate C1 in the thickness direction of the driving backplane and the projection of the second electrode plate C2 in the thickness direction of the driving backplane are extended beyond each other, in addition to determining the arrangement of the first electrode plate C1 included in the two adjacent capacitors Cst, in order to avoid the second electrode plate C2 included in the two adjacent capacitors Cst affecting the overall arrangement of the capacitor Cst, in this case, for the adjacent first capacitors Cst1 and the second capacitor Cst2, the second electrode plate C2 of the first capacitor Cst1 has a third side, and the second electrode plate C2 of the second capacitor Cst2 has a fourth side, the third side is opposite to the fourth side, and the straight lines where the third side and the fourth side are located form a second angle, which is an acute angle.

Optionally, the angle range of the difference between the first angle a formed by the straight lines where the first side L1 and the second side L2 are located and the second angle formed by the straight lines where the third side and the fourth side are located is greater than or equal to 0 degrees and less than or equal to 10 degrees, and the angle of the first angle a can be greater than the angle of the second angle, or the angle of the first angle a can be smaller than the second angle.

Optionally, the second angle may be greater than or equal to 5 degrees and less than or equal to 80 degrees, and for example, the second angle is 5 degrees, 0 degrees, 45 degrees, 60 degrees, 75 degrees, etc. Assume that the first angle a is greater than the second angle, and the angle difference between the two is 8 degrees, then for example, the first angle a is 49 degrees, and the second angle is 41 degrees.

In the embodiment of the present disclosure, in combination with the above case in which the top metal layer 123 is formed with a first conductive sheet E1 and a second conductive sheet E2, one of the first electrode plate C1 and the second electrode plate C2 is connected to the first conductive sheet E1, the control electrode of the driving transistor T1 is connected to the first conductive sheet E1 through the first via V1, the first electrode of the driving transistor T1 is connected to the second conductive sheet E2, the second electrode of the driving transistor T1 is used to input a voltage signal, and the second conductive sheet E2 is used to be connected to the light-emitting device through the second via V2.

Optionally, the cross-section of the first via V1 is a polygon, the edge V11 of the first via V1 connected to the first capacitor Cst1 faces the first side L1 of the first electrode plate C1 of the first capacitor Cst1 or the extension line of the first side L1, and the side wall V12 of the first via V1 connected to the first capacitor Cst1 faces the second side L2 of the first electrode plate C1 of the second capacitor Cst2.

In this way, by adjusting the position of the first via V1 having a polygonal cross-section, a safety gap between the first via V1 and the first electrode plate C1 of the first capacitor Cst1 and a safety gap between the first via V1 the first electrode plate C1 of the second capacitor Cst2 is ensured, while insuring the safety gap between first electrode plate C1 of the first capacitor Cst1 and the second electrode plate C2 of the second capacitor Cst2.

For example, the cross-sections of the first electrode plate C1 of the first capacitor Cst1, the first electrode plate C1 of the second capacitor Cst2, and the first via V1 are all rectangular; as shown in FIG. 5 and FIG. 8, the edge V11 of the first via V1 connected to the first capacitor Cst1 faces the first side L1 of the first electrode plate C1 of the first capacitor Cst1, and the minimum safety gap between the edge V11 of the first via V1 connected to the first capacitor Cst1 and the straight line where the first side L1 of the first electrode plate C1 of the first capacitor Cst1 is located is a; the side wall V12 of the first via V1 connected to the first capacitor Cst1 faces the first side L1 of the first electrode plate C1 of the second capacitor Cst2, and the minimum safety gap between the side wall V12 of the first via V1 connected to the first capacitor Cst1 and the first side L1 of the first electrode plate C1 of the second capacitor Cst2 is a, in this case, the gap between the first electrode plate C1 of the first capacitor Cst1 and the first electrode plate C1 of the second capacitor Cst2 is less than 2a+b, thereby reducing the spacing while ensuring the safety gap.

Of course, for the case where the cross-section of the first via V1 mentioned above is a polygon, the side wall V12 of the first via V1 connected to the first capacitor Cst1 may also face the first side L1 of the first electrode plate C1 of the first capacitor Cst1, and the edge V11 of the second via V2 connected to the first capacitor Cst1 may face the first side L1 of the first electrode plate C1 of the second capacitor Cst2, which is not limited by the disclosed embodiment.

It should be noted that, for the case where the second angle formed by the third side of the second electrode plate C2 of the first capacitor Cst1 and the fourth side of the second electrode plate C2 of the second capacitor Cst2 is an acute angle, in this case, the edge V11 of the first via V1 connected to the first capacitor Cst1 faces the third side of the second electrode plate C2 of the first capacitor Cst1 or the extension of the third side, and the minimum safety gap is a; the side wall V12 of the first via V1 connected to the first capacitor Cst1 faces the fourth side of the second electrode plate C2 of the second capacitor Cst2, and the minimum safety gap is a. As a result, the gap between the second electrode plate C2 of the first capacitor Cst1 and the second electrode plate C2 of the second capacitor Cst2 is less than 2a+b, thereby reducing the spacing under the premise of ensuring the safety gap.

In some embodiments, in combination with the above, when the first metal layer 121 further includes the third conductive sheet E3, since the third conductive sheet E3 is located between the first electrode plate C1 of the first capacitor Cst1 and the first electrode plate C1 of the second capacitor Cst2, in this case, it is necessary to adjust the distance between the first electrode plate C1 of the first capacitor Cst1 and the first electrode plate C1 of the second capacitor Cst2 according to the size of the third conductive sheet E3 to ensure that a safety gap is reserved between the third conductive sheet E3 and the first electrode plate C1 of the first capacitor Cst1, and between the third conductive sheet E3 and the first electrode plate C1 of the second capacitor Cst2.

Optionally, the third conductive sheet E3 is polygonal, and a corner of the third conductive sheet E3 connected to the first capacitor Cst1 faces the first side L1 of the first electrode plate C1 of the first capacitor Cst1 or the extension line of the first side L1, and a side of the third conductive sheet E3 connected to the first capacitor Cst1 faces the second side L2 of the first electrode plate C1 of the second capacitor Cst2.

In this way, by adjusting the position of the polygonal third conductive sheet E3 as mentioned above, the safe gap between third conductive sheet E3 and the first electrode plate C1 of the first capacitor Cst1 and the safe gap between third conductive sheet E3 and the first electrode plate C1 of the second capacitor Cst2 is ensured, while ensuring the safe gap between the first electrode plate C1 of the first capacitor Cst1 and the first electrode plate C1 of the second capacitor Cst2.

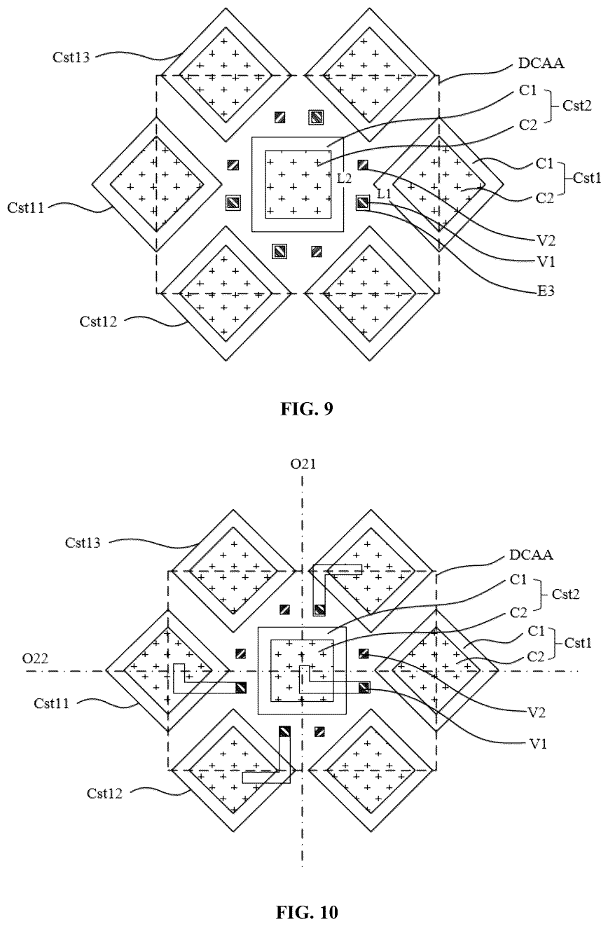

For example, the first electrode plate C1 of the first capacitor Cst1, the first electrode plate C1 of the second capacitor Cst2, and the third conductive sheet E3 are all rectangular; as shown in FIG. 9, the corner of the third conductive sheet E3 connected to the first capacitor Cst1 faces the first side L1, and the safety gap between the corner of the third conductive sheet E3 connected to the first capacitor Cst1 and the first side L1 is a; the side of the third conductive sheet E3 connected to the first capacitor Cst1 faces the second side L2, and the safety gap between the side of the third conductive sheet E3 connected to the first capacitor Cst1 and the second side L2 is a, at this time, the gap between the first electrode plate C1 of the first capacitor Cst1 and the first electrode plate C1 of the second capacitor Cst2 is less than 2a+c, thereby reducing the spacing under the premise of ensuring the safety gap. Wherein, the parameter c refers to the side length of the third conductive sheet E3.

Of course, for the case where the third conductive sheet E3 mentioned above is polygonal, the side of the third conductive sheet E3 connected to the first capacitor Cst1 can also face the first side L1 of the first electrode plate C1 of the first capacitor Cst1, and the corner of the third conductive sheet E3 connected to the first capacitor Cst1 can face the second side L2 of the first electrode plate C1 of the second capacitor Cst2 or the extension line of the second side L2, which is not limited by the embodiments of the present disclosure.

In the embodiment of the present disclosure, in conjunction with the above-described driving backplane having multiple pixel areas DCAA, as shown in FIG. 7, the multiple capacitors Cst include multiple groups of capacitors Cst distributed in an array, and a group of capacitors Cst at least includes capacitors Cst included in multiple pixel circuits corresponding to one pixel area DCAA.

In some embodiments, as shown in FIG. 5, a group of capacitors Cst includes a second capacitor Cst2 and six first capacitors Cst1 located around the second capacitor Cst2 and distributed circumferentially; two adjacent groups of capacitors Cst in the row direction share one first capacitor Cst1, and two adjacent groups of capacitors Cst in the column direction share two first capacitors Cst.

The row direction may be a horizontal direction, and the column direction may be a vertical direction; of course, after the array substrate 10 being rotated 90 degrees, the row direction may be a vertical direction, and the column direction may be a horizontal direction. In addition, taking the example that the driving backplane forms four pixel circuits in the pixel area DCAA, the four capacitors Cst in a group of capacitors Cst are the capacitors Cst included in the four pixel circuits, and the remaining capacitors Cst are the capacitors Cst included in the pixel circuits formed in the adjacent pixel area DCAA.

Optionally, as shown in FIG. 5, six first capacitors Cst1 are symmetrically distributed with respect to the center line O21 of the first electrode plate C1 of the second capacitor Cst2 in the column direction, that is, there are three first capacitors Cst1 on each side of the center line of the first electrode plate C1 of the second capacitor Cst2 in the column direction, and they are symmetrically distributed.

Taking the three first capacitors Cst1 located on the same side of the center line of the second capacitor Cst2 in the column direction being the first sub-capacitor Cst11, the second sub-capacitor Cst12 and the third sub-capacitor Cst13 as an example, as shown in FIG. 5, the center line O11 of the first electrode plate C1 of the first sub-capacitor Cst11 in the row direction coincides with the center line O22 of the first electrode plate C1 of the second capacitor Cst2 in the row direction, the second sub-capacitor Cst12 and the third sub-capacitor Cst13 are symmetrically distributed with respect to the center line O22 of the first electrode plate C1 of the second capacitor Cst2 in the row direction, and in the row direction, the center point O of the second sub-capacitor Cst12 is located between the first sub-capacitor Cst11 and the second capacitor Cst2.

The first sub-capacitor Cst11 is a capacitor Cst shared by two adjacent groups of capacitors Cst in the row direction, and the second sub-capacitor Cst12 and the third sub-capacitor Cst13 are capacitors Cst shared by two adjacent groups of capacitors Cst in the column direction.

In combination with the above-mentioned case that the top metal layer 123 has the first conductive sheet E1 and the second conductive sheet E2, the first conductive sheet E1 is connected to the control electrode of the driving transistor T1 through the first via hole V1, and the second conductive sheet E2 is connected to the light-emitting device through the second via hole V2, the periphery of the second capacitor Cst2 has multiple pairs of via holes, and each pair of via holes includes the first via hole V1 and the second via hole V2 of one pixel circuit. One pair of via holes in the multiple pairs of via holes is connected to the second capacitor Cst2, and the remaining other pairs of via holes are respectively connected to the corresponding first capacitors Cst1.

Optionally, as shown in FIG. 9, the cross-sections of the first via hole V1 and the second via hole V2 are both polygonal, and in this case the side walls of the first via hole V1 and the second via hole V2 are opposite to the side of the first electrode plate C1 of the second capacitor Cst2.

Hereinafter, taking the case where four pixel circuits are formed in a pixel area DCAA of the driving backplane and the first electrode plate C1 of the capacitor Cst is a rectangle as an example, each of the four sides of the first electrode plate C1 of the second capacitor Cst2 has a first via V1 and a second via V2 connected to the same capacitor Cst, and the first via V1 and the second via V2 connected to the same capacitor Cst are symmetrically distributed along the perpendicular bisector of the corresponding side of the first electrode plate C1 of the second capacitor Cst2.

Optionally, as shown in FIG. 10, the first via V1 and the second via V2 connected to the first sub-capacitor Cst11 are located on one side of the first sub-capacitor Cst11 in the row direction, and are symmetrically distributed with respect to the center line O22 of the first electrode plate C1 of the second capacitor Cst2 in the row direction; the first via V1 and the second via V2 connected to the second sub-capacitor Cst12 are located on one side of the center line O22 of the second sub-capacitor Cst12 in the row direction, and are symmetrically distributed with respect to the center line O21 of the first electrode plate C1 of the second capacitor Cst2 in the column direction.

For example, as shown in FIG. 10, the first via V1 and the second via V2 on one side of the second capacitor Cst2 in the row direction are connected to the first sub-capacitor Cst11, the first via V1 and the second via V2 on the other side of the second capacitor Cst2 in the row direction are connected to the second capacitor Cst2, the first via V1 and the second via V2 on one side of the second capacitor Cst2 in the column direction are connected to the second sub-capacitor Cst12 (or the sub-capacitor Cst symmetrically distributed with the second sub-capacitor Cst12), and the first via V1 and the second via V2 on the other side of the second capacitor Cst2 in the column direction are connected to the sub-capacitor Cst symmetrically distributed with the third sub-capacitor Cst13 (or the third sub-capacitor Cst13).

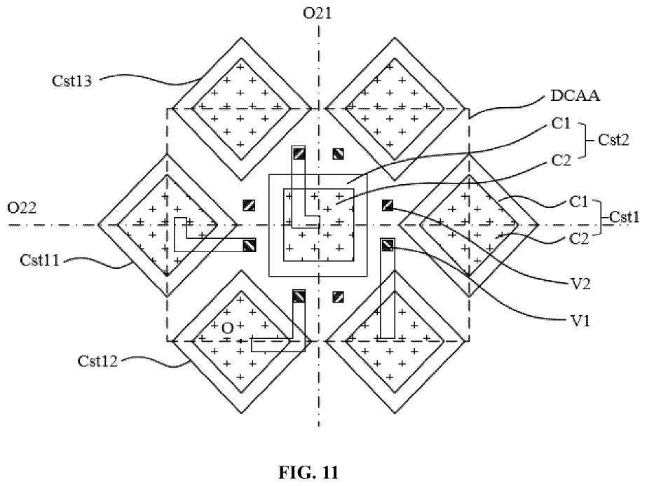

Alternatively, as shown in FIG. 11, the first via V1 and the second via V2 on one side of the second capacitor Cst2 in the row direction are connected to the first sub-capacitor Cst11, the first via V1 and the second via V2 on the other side of the second capacitor Cst2 in the row direction are connected to a sub-capacitor Cst symmetrically distributed with the second sub-capacitor Cst12 (or the sub-capacitor Cst symmetrically distributed with the third sub-capacitor Cst13), the first via V1 and the second via V2 on one side of the second capacitor Cst2 in the column direction are connected to the second sub-capacitor Cst12 (or the third sub-capacitor Cst13), and the first via V1 and the second via V2 on the other side of the second capacitor Cst2 in the column direction are connected to the second capacitor Cst2.

The embodiment of the present disclosure further provides a method for manufacturing an array substrate, which is used to manufacture the array substrate described in the above embodiment. The method comprises the following step S110.

Step S110, forming a driving backplane, a plurality of pixel circuits are formed at the driving backplane, the pixel circuits include capacitors, the capacitors each includes a first electrode plate and a second electrode plate whose projections in the thickness direction of the driving backplane have an overlapping area, the plurality of capacitors include adjacent first capacitors and second capacitors, the first electrode plate of the first capacitor has a first side, the first electrode plate of the second capacitor has a second side, the first side is opposite to the second side, and the straight lines where the first side and the second side are located form a first angle, which is an acute angle.

In the embodiment of the present disclosure, for the first side of the first electrode plate of the first capacitor and the second side of the first electrode plate of the second capacitor, the first angle formed by the straight lines where the first side and the second side are located is set to an acute angle, so that while ensuring a safe gap between the first electrode plate of the first capacitor and the first electrode plate of the second capacitor, the distance between the two adjacent first electrode plates can be further reduced, thereby facilitating further improving the PPI of the display panel while increasing the arrangement density of the capacitors.

In the embodiments of the present disclosure, in the above steps, the manufacturing process of the driving backplane can refer to the relevant technology, but when manufacturing the first electrode plate and the second electrode plate included in the driving backplane, the arrangement of the first electrode plate and the second electrode plate is specifically referred to the above embodiments, which will not be repeated again in the embodiments of the present disclosure.

The embodiment of the present disclosure further provides a display device, which includes the display panel 100 described in the above embodiment.

In the embodiment of the present disclosure, for the first side L1 of the first electrode plate C1 of the first capacitor Cst1 and the second side L2 of the first electrode plate C1 of the second capacitor Cst2, the first angle formed by the straight lines where the first side L1 and the second side L2 are located is set to an acute angle, so that while ensuring a safe gap between the first electrode plate C1 of the first capacitor Cst1 and the first electrode plate C1 of the second capacitor Cst2, the distance between the two adjacent first electrode plates C1 can be further reduced, thereby facilitating further improving the PPI of the display panel 100 while increasing the arrangement density of the capacitors Cst.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. An array substrate, comprising:
a driving backplane, formed with a plurality of pixel circuits, wherein the pixel circuits comprises capacitors having a first electrode plate and a second electrode plate, and projections of the first electrode plate and the second electrode plate in a thickness direction of the driving backplane have an overlapping area, wherein the capacitors comprises a first capacitor and a second capacitor adjacent to each other, wherein the first electrode plate of the first capacitor has a first side, and the first electrode plate of the second capacitor has a second side, wherein the first side is opposite to the second side, and wherein a straight line where the first side is located and a straight line where the second side is located form a first angle, and the first angle is an acute angle.

2. The array substrate according to claim 1, wherein the driving backplane comprises a top metal layer, the top metal layer comprises a first conductive sheet and a second conductive sheet arranged at intervals, one pixel circuit comprises a driving transistor, and a projection of a control electrode of the driving transistor in the thickness direction of the driving backplane and a projection of the first conductive sheet in the thickness direction of the driving backplane have an overlapping area;
one of the first electrode plate and the second electrode plate is connected to the first conductive sheet, the first conductive sheet is connected to the control electrode of the driving transistor through a first via hole, the first electrode of the driving transistor is connected to the second conductive sheet, the second electrode of the driving transistor is used to load a voltage signal, and the second conductive sheet is used to connect to the light-emitting device through a second via hole; and
a cross section of the first via hole is a polygon, an edge of the first via hole connected to the first capacitor faces the first side or an extension line of the first side, and a side wall of the first via hole connected to the first capacitor faces the second side.

3. The array substrate according to claim 2, wherein the driving backplane further comprises a third conductive sheet on a same layer as the first electrode plate, and the third conductive sheet is respectively connected to the first conductive sheet and the control electrode of the driving transistor; and
the third conductive sheet is polygonal in shape, a corner of the third conductive sheet connected to the first capacitor faces the first side or the extension line of the first side, and a side of the third conductive sheet connected to the first capacitor faces the second side.

4. The array substrate according to claim 2, wherein the pixel circuit comprises a write transistor, a first electrode of the write transistor is connected to the first conductive sheet, a second electrode of the write transistor is used to load a data signal, and a control electrode of the write transistor is used to load a scan signal.

5. The array substrate according to claim 4, wherein the pixel circuit comprises a switching transistor, a control electrode of the switching transistor is used to load an enable signal, a first electrode of the switching transistor is connected to a first electrode of the driving transistor, and a second electrode of the switching transistor is connected to the second conductive sheet.

6. The array substrate according to claim 2, wherein the driving backplane comprises a base substrate and a wiring layer, the driving transistor is integrated on the base substrate, and the wiring layer comprises the first electrode plate, the second electrode plate and the top metal layer.

7. The array substrate according to claim 2, wherein the plurality of capacitors comprise a plurality of groups of capacitors distributed in an array, and one group of capacitors comprises one second capacitor and six first capacitors located at a periphery of the second capacitor and distributed along a circumferential direction; and
two adjacent groups of capacitors in a row direction share one first capacitor, and two adjacent groups of capacitors in a column direction share two first capacitors.

8. The array substrate according to claim 7, wherein in a group of the capacitors, the six first capacitors are symmetrically distributed with respect to a center line of the first electrode plate of the second capacitor in a column direction; and
the six first capacitors comprise a first sub-capacitor, a second sub-capacitor and a third sub-capacitor located on a same side of the center line of the second capacitor in the column direction, a center line of the first sub-capacitor in the row direction coincides with a center line of the second capacitor in the row direction, the second sub-capacitor and the third sub-capacitor are symmetrically distributed with respect to the center line of the first electrode plate of the second capacitor in the row direction, and in the row direction, a center point of the second sub-capacitor is located between the first sub-capacitor and the second capacitor.

9. The array substrate according to claim 8, wherein the first electrode plate of the capacitor is rectangular, each of four sides of the first electrode plate of the second capacitor have a first via and a second via connected to a same capacitor among the first capacitor and the second capacitor, and the first via and the second via connected to the same capacitor are symmetrically distributed with respect to a perpendicular bisector of a corresponding side of the first electrode plate of the second capacitor.

10. The array substrate according to claim 1, wherein the driving backplane comprises a first metal layer and a second metal layer, the first metal layer comprises the first electrode plate of the capacitor, and the second metal layer comprises the second electrode plate of the capacitor; and
the projection of the second electrode plate in the thickness direction of the driving backplane is located within the projection of the first electrode plate in the thickness direction of the driving backplane.

11. The array substrate according to claim 1, wherein a first angle formed by the straight lines where the first side and the second side are located is greater than or equal to 5 degrees and less than or equal to 80 degrees.

12. The array substrate according to claim 11, wherein a first angle formed by the straight lines where the first side and the second side are located is 45 degrees.

13. The array substrate according to claim 2, wherein a distance between the first electrode plate of the first capacitor and the first electrode plate of the second capacitor is less than 2a+b, parameter a refers to a minimum safe gap between the first electrode plate and the first via hole, and parameter b is a side length of the cross section of the first via hole.

14. A method for manufacturing an array substrate, wherein the method comprises:
forming a driving backplane, wherein the driving backplane is formed with a plurality of pixel circuits, wherein the pixel circuits comprises capacitors having a first electrode plate and a second electrode plate, and projections of the first electrode plate and the second electrode plate in a thickness direction of the driving backplane have an overlapping area, wherein the capacitors comprises a first capacitor and a second capacitor adjacent to each other, wherein the first electrode plate of the first capacitor has a first side, and the first electrode plate of the second capacitor has a second side, wherein the first side is opposite to the second side, and wherein a straight line where the first side is located and a straight line where the second side is located form a first angle, and the first angle is an acute angle.

15. A display panel, comprising:
an array substrate, comprising a driving backplane, formed with a plurality of pixel circuits; and
a light-emitting layer, disposed on a side of the driving backplane, wherein the light-emitting layer is formed with a plurality of light-emitting devices, and one of the pixel circuits is connected to at least one of the light-emitting devices,
wherein the pixel circuits comprises capacitors having a first electrode plate and a second electrode plate, and projections of the first electrode plate and the second electrode plate in a thickness direction of the driving backplane have an overlapping area, wherein the capacitors comprises a first capacitor and a second capacitor adjacent to each other, wherein the first electrode plate of the first capacitor has a first side, and the first electrode plate of the second capacitor has a second side, wherein the first side is opposite to the second side, and wherein a straight line where the first side is located and a straight line where the second side is located form a first angle, and the first angle is an acute angle.

16. A display device, comprising the display panel according to claim 15.

17. The display panel according to claim 15, wherein the driving backplane comprises a top metal layer, the top metal layer comprises a first conductive sheet and a second conductive sheet arranged at intervals, one pixel circuit comprises a driving transistor, and a projection of a control electrode of the driving transistor in the thickness direction of the driving backplane and a projection of the first conductive sheet in the thickness direction of the driving backplane have an overlapping area;
one of the first electrode plate and the second electrode plate is connected to the first conductive sheet, the first conductive sheet is connected to the control electrode of the driving transistor through a first via hole, the first electrode of the driving transistor is connected to the second conductive sheet, the second electrode of the driving transistor is used to load a voltage signal, and the second conductive sheet is used to connect to the light-emitting device through a second via hole; and
a cross section of the first via hole is a polygon, an edge of the first via hole connected to the first capacitor faces the first side or an extension line of the first side, and a side wall of the first via hole connected to the first capacitor faces the second side.

18. The display panel according to claim 17, wherein the driving backplane further comprises a third conductive sheet on a same layer as the first electrode plate, and the third conductive sheet is respectively connected to the first conductive sheet and the control electrode of the driving transistor; and
the third conductive sheet is polygonal in shape, a corner of the third conductive sheet connected to the first capacitor faces the first side or the extension line of the first side, and a side of the third conductive sheet connected to the first capacitor faces the second side.

19. The display panel according to claim 17, wherein the pixel circuit comprises a write transistor, a first electrode of the write transistor is connected to the first conductive sheet, a second electrode of the write transistor is used to load a data signal, and a control electrode of the write transistor is used to load a scan signal.

20. The display panel according to claim 19, wherein the pixel circuit comprises a switching transistor, a control electrode of the switching transistor is used to load an enable signal, a first electrode of the switching transistor is connected to a first electrode of the driving transistor, and a second electrode of the switching transistor is connected to the second conductive sheet.
